(19) United States
(12) Patent Application Publication
(10) Pub. No.: US 2026/0167437 A1
(43) Pub. Date: Jun. 18, 2026

(54) WAFER TRANSFER DEVICE, WAFER LOADING AND UNLOADING DEVICE, AND CONTROL METHOD THEREOF

(71) Applicant: SEMIGHT INSTRUMENTS CO., LTD, Suzhou (CN)

(72) Inventors: Renwei TANG, Suzhou (CN); Zhe LIAN, Suzhou (CN); Jianjun HUANG, Suzhou (CN); Haiyang HU, Suzhou (CN)

(21) Appl. No.: 18/851,680

(22) PCT Filed: Jun. 18, 2024
(86) PCT No.: PCT/CN2024/099871

§ 371 Date: Sep. 27, 2024

(30) Foreign Application Priority Data
Feb. 8, 2024 (CN) 202410178006.1
Apr. 18, 2024 (CN) 202410469751.1

(51) Int. Cl. B65G 47/91

(52) U.S. Cl. CPC B65G 47/91

(57) ABSTRACT

A wafer transfer device includes a suction structure and a lifting structure that drives the suction structure to move vertically. The suction structure includes a first bracket, suction members, and snap-in parts. The first bracket is ring-shaped and connected to the lifting structure. The suction members are connected to and spaced apart along the circumferential direction of the first bracket, for providing suction forces to the bottom of a wafer concurrently to attach the wafer to a heat sink. The snap-in parts are connected to and spaced apart along the circumferential direction of the first bracket, for simultaneously clamping the heat sink carrying the wafer and providing suction forces to the heat sink to prevent the heat sink from falling off in movements with the suction structure.

### TECHNICAL FIELD

The present invention relates to the field of wafer testing technology and, more particularly, relates to a wafer transfer device, a wafer loading and unloading device, and control methods thereof.

### BACKGROUND

During wafer-level burn-in tests on wafers, it is needed to transfer wafers from a wafer cassette to a wafer-level burn-in test device. After a wafer-level burn-in test is completed, the wafers are transferred from the wafer-level burn-in test device to the wafer cassette. Thus, it is necessary to set up a wafer transfer device to transport wafers. If a wafer transfer device directly clamps a wafer, the wafer can be bent, deformed, or damaged easily. Thus a wafer needs to be placed on a heat sink, and then the heat sink with the wafer is transported by a wafer transfer device. It can avoid bending, deforming, or damaging the wafer. However, this handling method is prone to a wafer slipping off a heat sink, a heat sink moving around, or a heat sink slipping off a wafer transfer device during a transfer process. Thus, there is a need for a wafer transfer device that prevents wafer deformation and damage and ensures the stability of heat sink transportation.

In the existing technology, a portable wafer holder is often used to clamp a wafer first. Then the whole holder with the wafer is put in a burn-in test device for burn-in testing.

The portable wafer holder contains a heat sink and a probe board. As wafer sizes increase, if such kinds of holders are still used, the size of a needed holder becomes relatively large. It not only brings a certain degree of difficulty to the operation, but also reduces the test accuracy to a certain extent.

When the above-mentioned portable wafer holder is not used to fix and load wafers, a test chamber is usually set up in a burn-in test device. A robot hand can be used to pick up and load wafers. The robot hand transfers wafers directly from a wafer cassette to the test chamber for wafer-level burn-in tests. If a wafer is transported by directly clamping the wafer, the wafer can be bent, deformed, or damaged easily. To avoid such cases, a wafer needs to be placed on a heat sink first. Then, the heat sink with the wafer can be directly transported by a wafer transfer device. However, using such a method can cause cumbersome loading steps and a bulky loading device. Thus, there is a need for a wafer loading and unloading method that has simple loading steps, a short transfer distance, and high reliability.

### SUMMARY OF THE INVENTION

An object of one aspect of the invention is to provide a wafer transfer device, solving technical problems such as wafer being prone to falling off and deformed during wafer transportation.

A further object of one aspect of the invention is to improve clamping stability of a heat sink.

Another object of one aspect of the invention is to provide a wafer loading and unloading device.

An object of another aspect of the invention is to provide a control method for a wafer loading and unloading device, solving technical problems in the existing technology that wafer loading steps are cumbersome and loading devices are bulky.

A further object of another aspect of the invention is to improve stability during wafer transportation processes.

In particular, according to one aspect of the invention, a wafer transfer device is provided for transporting a heat sink that carries a wafer. The wafer transfer device includes a suction structure and a lifting structure that can drive the suction structure to move vertically.

The suction structure includes:
A first bracket with a ring shape and connected with the lifting structure;
Multiple suction members that are arranged at intervals along the circumferential direction of the first bracket and connected to the first bracket, wherein the suction members are configured to provide suction forces to the bottom of the wafer at the same time, so that the wafer is attached to the heat sink; and
Multiple snap-in parts that are arranged at intervals along the circumferential direction of the first bracket and connected to the first bracket, wherein the snap-in parts are configured to simultaneously clamp the heat sink carrying the wafer in a controlled manner, and provide suction forces to the heat sink. It prevents the heat sink carrying the wafer from falling off while moving with the suction structure.

In particular, the invention provides a wafer loading and unloading device that includes:
The above-mentioned wafer transfer device used to place the heat sink carrying the wafer in a test chamber of a wafer-level burn-in test device or to take the heat sink out from the test chamber;
A heat sink test device provided next to the wafer transfer device and having a mounting platform for placing the heat sink, wherein the mounting platform is configured to controllably extend out of the heat sink test device, so that the wafer transfer device may place the heat sink carrying the wafer on the mounting platform or takes out the heat sink carrying the wafer from the mounting platform; and
A wafer pick-up device disposed next to the heat sink test device, wherein the wafer pickup device is configured to take out a wafer from a wafer cassette, calibrate the position of the wafer, and then put the wafer on the heat sink at the mounting platform, and the wafer pick-up device is further configured to take out the wafer from the heat sink and put it in the wafer cassette.

In particular, according to another aspect of the invention, a control method for a wafer loading and unloading device is provided. The method includes the following steps:
After placing a heat sink carrying a target wafer on a mounting platform of a heat sink test device, controlling the mounting platform to extend laterally toward a wafer-level burn-in test device;
Controlling a suction structure to clamp the heat sink carrying the target wafer;
After the mounting platform is controlled to reset, controlling a pressure-bearing platform of the wafer-level burn-in test device to extend laterally toward the heat sink test device;
Controlling the suction structure to place the heat sink carrying the target wafer in the lower sealing cover of the pressure-bearing platform; and
After the pressure-bearing platform is controlled to reset, controlling the lower sealing cover to dock to a cover plate assembly to form a test chamber for wafer-level burn-in testing.

According to some embodiments of the invention, multiple suction members are used to suck the bottom of the wafer, making the wafer attaching to the heat sink. It may prevent the wafer from moving and falling off. In addition, multiple snap-in parts are used to clamp the heat sink carrying the wafer. The snap-in parts also provide suction forces on the heat sink, thereby preventing the heat sink from falling off during transportation and improving the stability of the heat sink movement. In the invention, not only the wafer is sucked, but also the heat sink is sucked. By double suction, it ensures the stability of the wafer and heat sink during transportation and prevents the wafer and heat sink from falling off the suction structure.

Further, in the invention, after receiving signals of contact with the heat sink fed back from multiple suction members at the same time, a controller is configured to control a first power source to drive an annular connector to rotate, so as to drive a sliding component to drive a snap-in part to move to clamp the heat sink. When multiple suction members feedback contact information with the heat sink concurrently, it indicates that the heat sink is in a horizontal state, not tilted, and there is no need to adjust the position of the heat sink. Multiple snap-in parts may be directly controlled to clamp the heat sink. It may avoid unstable clamping and heat sink falling off due to a tilted heat sink. Clamping stability of the heat sink is improved.

According to some other embodiments of the invention, in a process where a heat sink carrying a target wafer is transferred from a heat sink test device to a wafer-level burn-in test device, after the heat sink carrying the target wafer is placed on a mounting platform of the heat sink test device, the mounting platform of the heat sink test device is controlled to extend sideways toward the wafer-level burn-in test device first. Thereafter, a suction structure is controlled to clamp the heat sink. Then, after the mounting platform is controlled to reset, a pressure-bearing platform of the wafer-level burn-in test device is controlled to extend laterally toward the heat sink test device. The suction structure is controlled to place the heat sink in a lower sealing cover of the pressure-bearing platform. Finally, after the pressure-bearing platform is controlled to reset, the lower sealing cover is controlled to dock to a cover plate assembly to form a test chamber for wafer-level burn-in testing. With the above-mentioned technical solution, transfer of the heat sink is realized by respectively and laterally extending the mounting platform of the heat sink test device and the pressure-bearing platform of the wafer-level burn-in test device, combined with the movement of the suction structure. It simplifies wafer loading steps, shortens the wafer transfer distance, and makes the loading device more compact.

Further, during a process where a suction structure is controlled to clamp a heat sink carrying a target wafer, after it is determined that any of the snap-in parts of the suction structure is open, the suction structure is controlled to move downward, and then any of the snap-in parts of the suction structure is controlled to suck the target wafer. Thereafter, any snap-in part is controlled to clamp the heat sink, and finally any snap-in part is controlled to suck the heat sink. That is, the suction structure not only clamps the heat sink carrying the target wafer, but also simultaneously sucks the target wafer and heat sink, respectively. It improves the transfer stability of the heat sink carrying the target wafer during transportation, and prevents the target wafer from falling, bending, or being damaged during transportation.

From the following detailed description of embodiments of the invention in conjunction with the accompanying drawings, those skilled in the art may further understand the above and other objectives, advantages, and features of the invention.

### BRIEF DESCRIPTION OF THE DRAWINGS

Some specific embodiments of the present invention will be described in detail below by way of illustration and not limitation with reference to the accompanying drawings. The same reference numbers in the drawings identify the same or similar parts or portions. Those skilled in the art will appreciate that these drawings are not necessarily drawn to scale.

FIG. 1 is a schematic structural diagram of a wafer transfer device according to an embodiment of the invention;

FIG. 2 is a schematic enlarged view of a suction structure of the wafer transfer device shown in FIG. 1;

FIG. 3 is a schematic top view of the suction structure of the wafer transfer device shown in FIG. 1;

FIG. 4 is a schematic structural diagram of a snap-in part and sliding component according to an embodiment of the invention;

FIG. 5 is a schematic perspective view of a snap-in part according to an embodiment of the invention;

FIG. 6 is a schematic enlarged view of a drive assembly according to an embodiment of the invention;

FIG. 7 is a schematic perspective view of the interior of a heat sink according to an embodiment of the invention;

FIG. 8 is a schematic structural diagram of a heat sink according to an embodiment of the invention;

FIG. 9 is a schematic perspective view of a second air channel inside a heat sink according to an embodiment of the invention;

FIG. 10 is a schematic cross-sectional view of a suction member according to an embodiment of the invention;

FIG. 11 is a schematic structural diagram of a wafer loading and unloading device according to the invention;

FIG. 12 is a schematic structural diagram of a wafer-level burn-in test device according to an embodiment of the invention;

FIG. 13 is a schematic cross-sectional view of a second bracket of a wafer loading and unloading device according an embodiment of to the invention;

FIG. 14 is a schematic flow chart of a control method for a wafer loading and unloading equipment according to an embodiment of the invention;

FIG. 15 is a schematic flow chart of another control method for a wafer loading and unloading equipment according to an embodiment of the invention;

FIG. 16 is a schematic block diagram of a wafer loading and unloading device according to an embodiment of the invention;

FIG. 17 is a schematic connection diagram of a suction structure and a lifting structure according to an embodiment of the invention;

FIG. 18 is a schematic structural diagram of a suction structure according to an embodiment of the invention;

FIG. 19 is a schematic structural diagram of a wafer pick-up device and a heat sink test device according to an embodiment of the invention;

FIG. 20 is a schematic structural diagram of a pressure-bearing platform of a wafer-level burn-in test device in an original state according to an embodiment of the invention;

FIG. 21 is a schematic structural diagram of a pressure-bearing platform of a wafer-level burn-in test device in a extend-out state according to an embodiment of the invention;

FIG. 22 is a schematic structural diagram of a suction structure placing a heat sink in a lower sealing cover according to an embodiment of the invention;

FIG. 23 is a schematic structural diagram of a suction structure taking a heat sink from a mounting platform according to an embodiment of the invention;

FIG. 24 is a schematic partial view of a suction structure according to an embodiment of the invention;

FIG. 25 is a schematic structural diagram of a snap-in part and sliding component according to an embodiment of the invention;

FIG. 26 is a schematic cross-sectional view of a snap-in part according to an embodiment of the invention;

FIG. 27 is a schematic structural diagram of a heat sink according to an embodiment of the invention;

FIG. 28 is a schematic cross-sectional view of a heat sink according to an embodiment of the invention;

FIG. 29 is a schematic enlarged view of a part A in FIG. 28;

FIG. 30 is a schematic cross-sectional view of a suction member according to an embodiment of the invention; and

FIG. 31 is a schematic flow chart of a control method for a wafer loading and unloading equipment according to an embodiment of the invention.

### DETAILED DESCRIPTION

The embodiments of the invention are described in detail below. Examples of the embodiments are illustrated in the drawings, wherein the same or similar reference numerals throughout represent the same or similar elements or elements having the same or similar functions. The embodiments described below with reference to the drawings are exemplary and intended to explain the invention and are not to be construed as limiting the present invention.

In describing the invention, it is to be understood that the orientation or positional relationship indicated by terms “upper”, “lower”, “left”, and “right” are based on the orientation or positional relationship shown in the drawings. The terms are used for describing the invention and simplifying descriptions, and not used for indicating or implying that a device or element referred to must have a particular orientation, or be constructed and operated in a particular orientation. The terms cannot be construed as limitations of the invention.

Terms “first” and “second” are used for descriptive purposes only and cannot be understood as indicating or implying relative importance or implicitly indicating the number of indicated technical features. Features defined as “first” and “second” may explicitly or implicitly include at least one of the features, that is, include one or more of the features. In the description of the invention, “multiple” means at least two, such as two, three, etc, unless otherwise expressly and specifically limited. When a certain feature “includes or comprises” one or more features it encompasses, unless specifically stated otherwise, this indicates that other features are not excluded and may further be included.

Unless otherwise expressly stated and limited, terms “connection”, “installation” are interpreted broadly. For example, it may be a fixed connection, a detachable connection, or an integrated body; a mechanical connection, or an electrical connection; directly connected or indirectly connected through an intermediary; or an internal connection between two components, or an interaction between two components, unless otherwise expressly limited.

Those of ordinary skill in the art should be able to understand the specific meanings of the above terms in the invention according to specific circumstances.

Unless otherwise limited, all terms (including technical terms and scientific terms) used in descriptions of the embodiments have the same meanings as that commonly understood by those of ordinary skill in the technical field to which this application belongs.

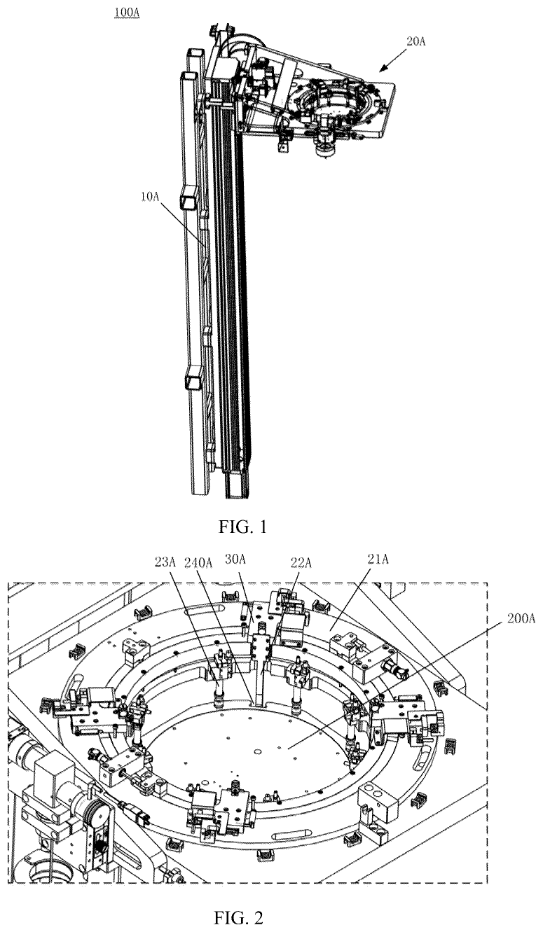

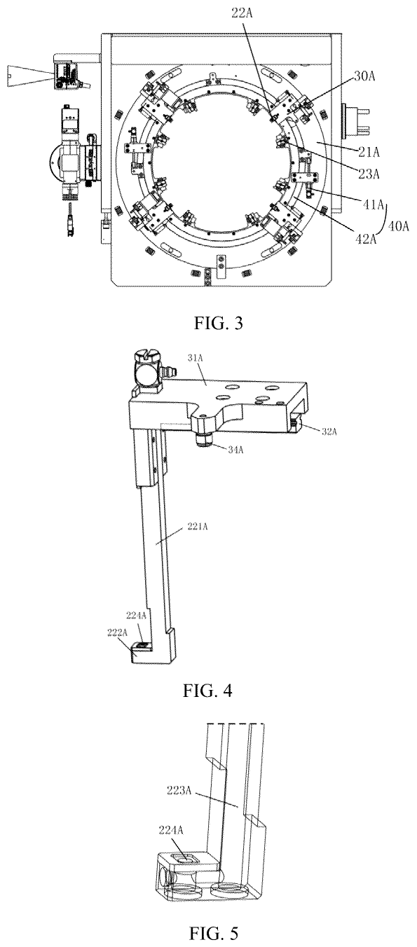

FIG. 1 is a schematic structural diagram of a wafer transfer device 100A according to an embodiment of the invention. FIG. 2 is a schematic enlarged view of a suction structure 20A of the wafer transfer device shown in FIG. 1. FIG. 3 is a schematic top view of the suction structure 20A of the wafer transfer device 100A shown in FIG. 1. As shown in FIGS. 1-3, in an embodiment, the wafer transfer device 100A is used to transport a heat sink 200A carrying a wafer. The wafer transfer device 100A includes the suction structure 20A and a lifting structure 10A that drives the suction structure 20A to move vertically. The suction structure 20A includes a first bracket 21A, multiple suction members 23A, and multiple snap-in parts 22A. The first bracket 21A is annular and connected to the lifting structure 10A. The suction members 23A are arranged at intervals along the circumferential direction of the first bracket 21A, and connected to the first bracket 21A. The suction members 23A are arranged to provide suction forces to the bottom of the wafer at the same time, so that the wafer is attached to the heat sink 200A. The snap-in parts 22A are spaced apart along the circumferential direction of the first bracket 21A, and connected to the first bracket 21A. The snap-in parts 22A are configured to simultaneously clamp the heat sink 200A carrying the wafer in a controlled manner and provide suction forces on the heat sink 200A, thereby preventing the heat sink 200A carrying the wafer from falling off while the heat sink 200A moves with the suction structure 20A. The suction members 23A and snap-in parts 22A are staggered, so that the snap-in parts 22A and suction members 23A are evenly arranged on the first bracket 21A. The lifting structure 10A may drive the suction structure 20A to move up and down.

In the embodiment, the bottom of the wafer is sucked by multiple suction members 23A, so that the wafer is attached to the heat sink 200A, which prevents the wafer from moving and falling off. In addition, the heat sink 200A carrying the wafer is simultaneously clamped by multiple snap-in parts 22A. The snaps-in parts 22A also provide suction forces on the heat sink 200A. It prevents the heat sink 200A from falling off during transportation and improves the movement stability of the heat sink 200A. In the invention, suction is applied not only to the wafer, but also to the heat sink 200A. Through double suction, it ensures the stability of the wafer and the heat sink 200A during transportation processes and prevents the wafer and heat sink 200A from falling off the suction structure 20A.

In the embodiment, the wafer transfer device 100A also includes multiple sliding components 30A. Each sliding component 30A corresponds to a snap-in part 22A and is used for sliding connection between the snap-in part 22A and the first bracket 21A. As such, the snap-in part 22A slides in radial directions of the first bracket 21A in a controlled manner, thereby switching between a first position of clamping the heat sink 200A and a second position of separation from the heat sink 200A. It can be understood as that all sliding components 30A may simultaneously drive corresponding snap-in parts 22A to move toward the center of the first bracket 21A, thereby supporting the heat sink 200A at the same time. At this time, the snap-in part 22A is positioned at the first position. When all sliding components 30A simultaneously drive corresponding snap-in parts 22A to return to their original positions, i.e., moving away from the center position of the first bracket 21A, the support for the heat sink 200A may be removed. At this time, the snap-in part 22A is positioned at the second position.

FIG. 4 is a schematic structural diagram of the snap-in part 22A and sliding component 30A according to an embodiment of the invention. FIG. 5 is a schematic perspective view of the snap-in part 22A according to an embodiment of the invention. As shown in FIGS. 4 and 5, and referring to FIGS. 1 to 3, the snap-in part 22A is L-shaped and has a vertical part 221A and a horizontal part 222A. The horizontal part 222A is configured to abut the bottom of the heat sink 200A when the snap-in part 22A moves toward the center direction of the first bracket 21A to support the heat sink 200A. As shown in FIG. 2, notches 240A are provided on the peripheral side of the heat sink 200A. Each notch 240A corresponds to a snap-in part 22A. The snap-in part 22A moves from the notch 240A until the horizontal part 222A is below the heat sink 200A, thereby being able to support the heat sink 200A. When the horizontal part 222A of the snap-in part 22A moves to the notch 240A, the support for the heat sink 200A is removed.

In the embodiment, a first air channel 223A is provided inside the snap-in part 22A to suck the heat sink 200A when the snap-in part 22A abuts the bottom of the heat sink 200A. As shown in FIG. 5, the top of the horizontal part 222A has a suction mouth 224A connected with the first air channel 223A. The heat sink 200A is sucked through the suction mouth 224A. In the embodiment, not only the wafer is sucked, but also the bottom of the heat sink 200A is sucked. It prevents the heat sink 200A from moving or slipping off.

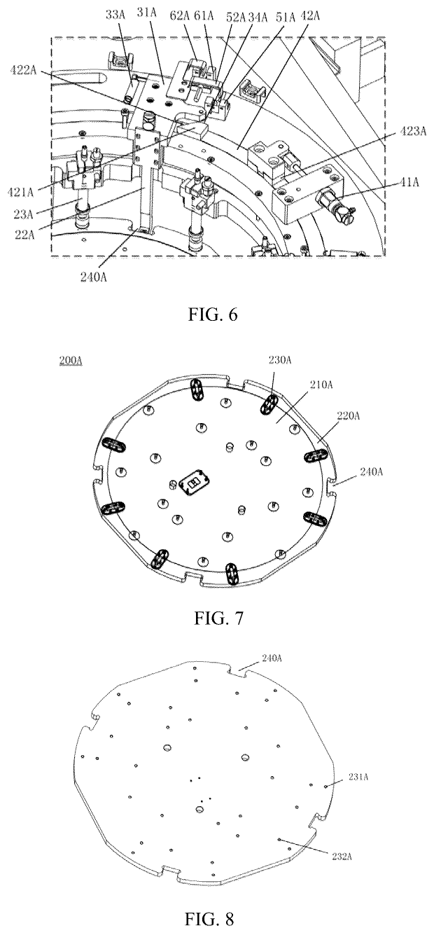

FIG. 6 is a schematic enlarged view of a drive assembly 40A according to an embodiment of the invention. As shown in FIG. 6, the wafer transfer device 100A further includes the drive assembly 40A. The drive assembly 40A is disposed on the first bracket 21A. The driving assembly 40A cooperates with multiple snap-in parts 22A and sliding components 30A, and simultaneously drives the snap-in parts 22A to switch between the first position and the second position in a controlled manner. That is, the drive assembly 40A may drive multiple sliding components 30A at the same time, making corresponding snap-in parts 22A to move.

In the embodiment, the drive assembly 40A includes at least one first power source 41A and an annular connector 42A. The first power source 41A is installed on the top of the first bracket 21A. The annular connector 42A is installed on the first bracket 21A and arranged concentrically with the first bracket 21A. The annular connector 42A is connected to the first power source 41A and cooperates with multiple sliding components 30A. The annular connector 42A is configured to be driven to rotate by the first power source 41A, and drives multiple sliding components 30A to slide at the same time, thereby driving multiple snap-in parts 22A to move simultaneously. In the embodiment, the first power source 41A is a pen-type cylinder. In some other embodiments, the first power source 41A may also have other structures, such as a rack and pinion structure. In the embodiment, the number of the first power source 41A is two, and the two first power sources 41A are spaced apart on the first bracket 21A. In some other embodiments, the number of the first power source 41A may also be set according to specific design requirements. For example, the number of the first power source 41A may be set according to the diameter of the annular connector 42A. The larger the diameter of the annular connector 42A is, the greater the number of the first power sources 41A is. The smaller the diameter of the annular connector 42A is, the smaller the number of the first power sources 41A is.

Referring to FIGS. 4 and 6, the sliding component 30A includes an upper sliding part 31A connected to the snap-in part 22A and a lower sliding part 32A connected to the first bracket 21A. The upper sliding part 31A is provided with a contact portion 34A. The annular connector 42A is provided with multiple first protrusions 421A with an inclined surface 422A.

Each first protrusion 421A corresponds to a contact portion 34A of the sliding component 30A. The first protrusion 421A is configured to cause the contact portion 34A to slide along the inclined surface 422A during rotation of the annular connector 42A, thereby driving the upper sliding part 31A to slide along the lower sliding part 32A. That is, rotation of the annular connector 42A may cause the first protrusion 421A to move. At this time, the contact portion 34A may move upward or downward along the inclined surface 422A. When the annular connector 42A rotates clockwise, the contact portion 34A moves downward along the inclined surface 422A, and the upper sliding part 31A drives the snap-in part 22A to move toward the center of the first bracket 21A until the snap-in part 22A reaches the first position. When the annular connector 42A rotates counterclockwise, the contact portion 34A moves upward along the inclined surface 422A, and the upper sliding part 31A drives the snap-in part to move away from the center of the first bracket 21A until the snap-in part 22A reaches the second position. In the embodiment, by arranging the first protrusions with the inclined surface 422A ingeniously, the movement of the snap-in part is realized. The structure is simple and easy to implement. Further, the annular connector 42A is also provided with multiple second protrusions 423A. Each second protrusion 423A is provided with a groove. Each second protrusion 423A is connected to a connecting piece that matches the groove, and the connecting piece is connected to the first power source 41A. Thus, the first power source 41A drives the annular connector 42A to rotate through the cooperation between the connecting piece and the second protrusion 423A. In the embodiment, one end of the upper sliding part 31A is also connected to the first bracket 21A through an elastic member 33A. When the snap-in part 22A is at the second position, the elastic member 33A is in a stretched state. When the snap-in part 22A is at the first position, the elastic member 33A returns to its original shape.

Referring to FIG. 6, the wafer transfer device 100A further includes multiple first sensors 51A and multiple second sensors 61A. The first sensors 51A are installed on the first bracket 21A. Each first sensor 51A corresponds to a sliding component 30A and is used to detect whether a corresponding snap-in part 22A is in the first position. The second sensors 61A are installed on the first bracket 21A. Each second sensor 61A corresponds to a sliding component 30A and is used to detect whether a corresponding snap-in part 22A is in the second position. It may be understood that each sliding component 30A is configured with a first sensor 51A and a second sensor 61A. The upper sliding part 31A of the sliding component 30A is connected with a first limiting part 52A and a second limiting part 62A. The first limiting part 52A is used to cooperate with the first sensor 51A, while the second limiting part 62A is used to cooperate with the second sensor 61A. When the first sensor 51A senses the first limiting portion 52A, it indicates that the snap-in part 22A reaches the first position. When the second sensor 61A senses the second limiting portion 62A, it indicates that the snap-in part 22A reaches the second position.

In the embodiment, the wafer transfer device 100A also includes a controller (not shown). The controller is respectively connected to multiple suction members 23A, the first power source 41A, the first sensor 51A, and the second sensor 61A. The controller drives the sliding component 30A to drive the snap-in part 22A to move, so that the snap-in part 22A clamps the heat sink 200A. When multiple suction members 23A feed back contacting with the heat sink 200A at the same time, it indicates the heat sink 200A is in a horizontal state, not tilted, there is no need to adjust the position of the heat sink 200A, and the snap-in parts 22A may be controlled directly to clamp the heat sink 200A. It avoids tilting of the heat sink 200A, thereby preventing unstable clamping that may cause the heat sink 200A to fall off. The clamp stability of the heat sink 200A is improved.

In the embodiment, the controller is configured to control the first power source 41A to drive the annular connector 42A to move in the circumferential direction of the first bracket 21A, after simultaneously receiving feedback signals from multiple suction members 23A about contacting the heat sink 200A. The controller is also configured to control the snap-in part 22A to suck the heat sink 200A, after receiving signals fed back by the first sensor 51A. Then, the lifting structure 10A is controlled to drive the suction structure 20A to move vertically. The controller is also configured to control the lifting structure 10A to drive the suction structure 20A to move vertically, after receiving feedback signals from the second sensor 61A.

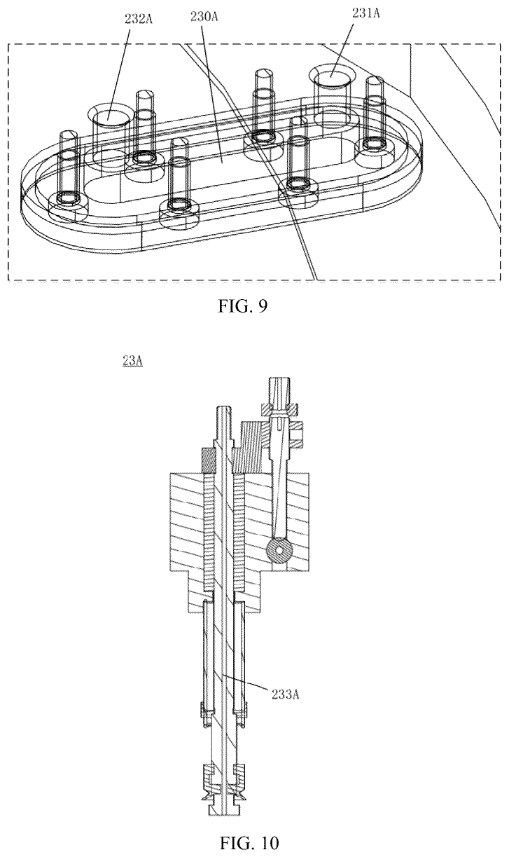

FIG. 7 is a schematic perspective view of the interior of the heat sink 200A according to an embodiment of the invention. FIG. 8 is a schematic structural diagram of the heat sink 200A according to an embodiment of the invention. FIG. 9 is a schematic perspective view of a second air channel 230A inside the heat sink 200A according to an embodiment of the invention. As shown in FIGS. 7-9, in the embodiment, the top of the heat sink 200A is provided with a first area 210A for placing the wafer and a second area 220A. The second area 220A includes areas other than the first area 210A at the top of the heat sink 200A. Multiple second air channels 230A are arranged inside the heat sink 200A. Each second air channel 230A corresponds to a suction member 23A. Each second air channel 230A further includes first air holes 232A in the first area 210A and second air holes 231A in the second area 220A.

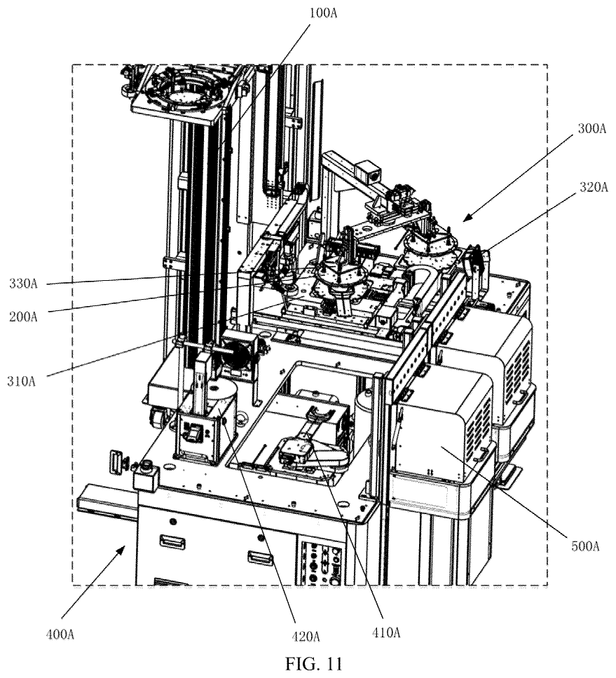

FIG. 10 is a schematic cross-sectional view of the suction member 23A according to an embodiment of the invention. As shown in FIG. 10 and referring to FIG. 6, a third air channel is provided inside the suction member 23A and extends downward from the first bracket 21A. The third air channel is configured to communicate with a second air hole 231A of a corresponding second air channel 230A when the suction member 23A abuts the heat sink 200A. A wafer is sucked through the second air hole 231A, the second air channel 230A, and the first air hole 232A sequentially. In the embodiment, the number of the second air channel 230A is eight, and each second air channel 230A corresponds to a suction member 23A. In some other embodiments, the number of the second air channel 230A may be set according to actual needs.

FIG. 11 is a schematic structural diagram of a wafer loading and unloading device (or equipment) according to an embodiment of the invention. As shown in FIG. 11, the wafer loading and unloading device includes the above-mentioned wafer transfer device 100A, the heat sink test device 300A, and a wafer pick-up device 400A. The wafer transfer device 100A is used to place the heat sink 200A carrying the wafer inside the test chamber of the wafer-level burn-in test device 610A, or take the heat sink 200A carrying the wafer out of the test chamber. The heat sink test device 300A is disposed next to the wafer transfer device 100A, and has a mounting platform 310A for placing the heat sink 200A. The mounting platform 310A is configured to extend out of the heat sink test device 300A in a controlled manner. As such, the wafer transfer device 100A may place the heat sink 200A carrying the wafer on the mounting platform 310A or take out the heat sink 200A carrying the wafer from the mounting platform 310A. The wafer pick-up device 400A is disposed next to the heat sink test device 300A. The wafer pick-up device 400A is configured to take the wafer from a wafer cassette 500A and perform position calibration on the wafer. The wafer pick-up device 400A then places the wafer on the heat sink 200A at the mounting platform 310A. The wafer pick-up device 400A is also configured to take the wafer on the heat sink 200A and transfer the wafer to the wafer cassette 500A.

In the embodiment, the heat sink test device 300A is provided with a first gripper 330A for sucking the heat sink 200A. When dust is detected on the heat sink 200A, the first gripper 330A may move the heat sink 200A to a fan 320A next to the mounting platform 310A for dust cleaning. Thereafter, the cleaned heat sink 200A is placed again on the mounting platform 310A by the first gripper 330A. The mounting platform 310A of the heat sink test device 300A may extend out to the left and reach a position below the suction structure 20A. Then after moving down, the suction structure 20A may take or place the heat sink 200A carrying the wafer.

In the embodiment, the wafer pick-up device 400A has a second gripper 410A. The second gripper 410A first takes out a wafer to be tested from the wafer cassette 500A, and then places the wafer on a wafer position calibration station 420A for position calibration. After the wafer position is calibrated, the second gripper 410A moves in a direction towards the heat sink test device 300A and places the wafer on the heat sink 200A of the mounting platform 310A of the heat sink test device 300A. Thereafter, the wafer and heat sink 200A may be regarded as one body and transported together during the entire moving process. In other words, inside the heat sink test device 300A and the wafer transfer device 100A, the heat sink 200A and the wafer may be regarded as one body and are transported together.

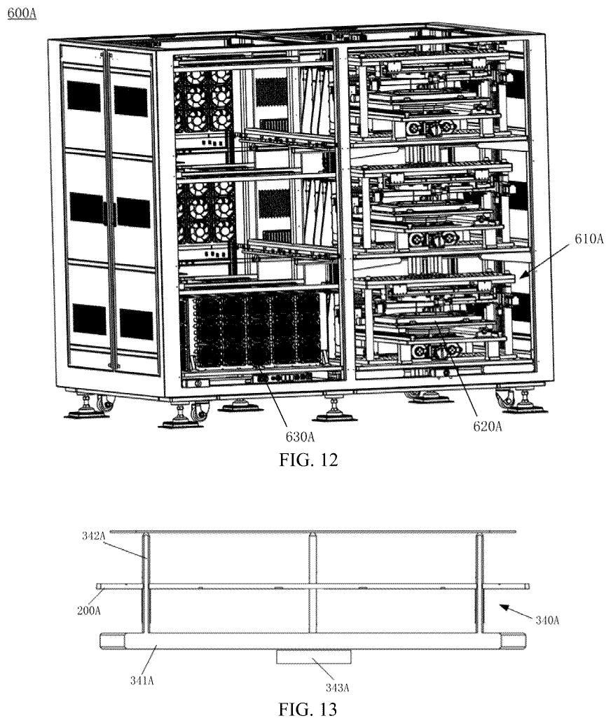

FIG. 12 is a schematic structural diagram of a wafer-level burn-in test equipment 600A according to an embodiment of the invention. As shown in FIG. 12, in the embodiment, a wafer-level burn-in test apparatus 610A is placed in the wafer-level burn-in test equipment 600A. The wafer-level burn-in test equipment 600A has multiple vertically arranged placement spaces for placing the wafer-level burn-in test apparatus 610A. Each placement space is configured for placing a wafer-level burn-in test apparatus 610A. Each wafer-level burn-in test apparatus 610A may perform burn-in tests on wafers. In the embodiment, the wafer-level burn-in test equipment 600A and the heat sink test device 300A are relatively arranged on the left and right sides of the wafer transfer device 100A. The wafer transfer device 100A may place the heat sink 200A carrying the wafer in a test chamber of the lower sealing cover 620A of any wafer-level burn-in test apparatus 610A, and the lower sealing cover 620A only needs to extend out of the wafer-level burn-in test equipment 600A. The lower sealing cover 620A of each wafer-level burn-in test apparatus 610A may extend to a position below the suction structure 20A. In addition, the wafer-level burn-in test equipment 600A also includes a heat dissipation component 630A that dissipates heat from the wafer-level burn-in test apparatus 610A. It prevents the wafer-level burn-in test apparatus 610A from overheating. In the embodiment, multiple sensing devices are disposed in the wafer-level burn-in test equipment 600A. Each wafer-level burn-in test apparatus 610A is connected to a sensing device for performing wafer-level burn-in testing on wafers.

FIG. 13 is a schematic cross-sectional view of a second bracket 340A of a wafer loading and unloading equipment according to an embodiment of the invention. As shown in FIG. 13, the mounting platform 310A includes the second bracket 340A that may go up and down in the vertical direction. When a wafer 700A is placed on the mounting platform 310A, the second bracket 340A rises through the heat sink 200A to receive the wafer 700A. When the wafer 700A is being transported, the second bracket 340A is lowered down and gets separated from the heat sink 200A, so that the wafer 700A attaches to the heat sink 200A.

Specifically, the second bracket 340A includes a second power source 343A, at least one lifting column 342A, and a base 341A. The second power source 343A is connected to the base 341A, and the base 341A is connected to the lifting column 342A. The lifting column 342A may pass through a corresponding hole of the heat sink 200A. The second power source 343A drives the lifting column 342A to rise and fall. In the embodiment, the number of the lifting column 342A is three.

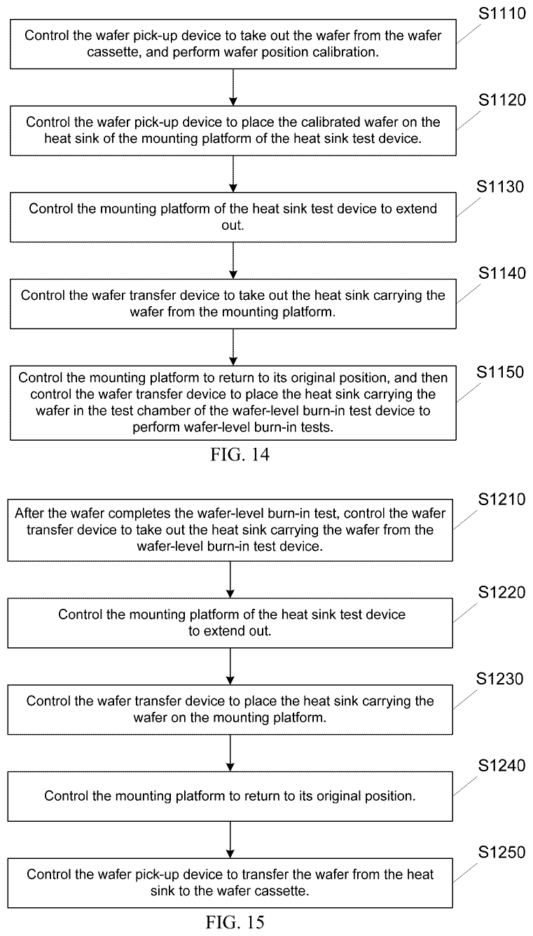

FIG. 14 is a schematic flow chart of a control method of a wafer loading and unloading equipment according to an embodiment of the invention. As shown in FIG. 14, in the embodiment, the control method of the wafer loading and unloading equipment includes the following steps:
Step S1110, controlling the wafer pick-up device 400A to take out the wafer from the wafer cassette 500A, and performing wafer position calibration;
Step S1120, controlling the wafer pick-up device 400A to place the wafer with position calibration on the heat sink 200A of the mounting platform 310A of the heat sink test device 300A;
Step S1130, controlling the mounting platform 310A of the heat sink test device 300A to extend out;
Step S1140, controlling the wafer transfer device 100A to take out the heat sink 200A carrying the wafer from the mounting platform 310A; and
Step S1150, controlling the mounting platform 310A to reset (i.e., returning to the original position), and then controlling the wafer transfer device 100A to place the heat sink carrying the wafer in the test chamber of the wafer-level burn-in test apparatus 610A to perform wafer-level burn-in tests.

In the embodiment, through the above-illustrated control methods, fully automatic loading of wafers may be realized without personnel participation. It reduces labor costs and improves testing efficiency.

At Step S1110, the second gripper 410A of the wafer pick-up device 400A is provided with a scanning device. Before grasping the wafer, the scanning device scans the wafer cassette to determine the location of the wafer. Then the second gripper 410A is used to grip the wafer.

At Step S1120, during the process when the second gripper 410A of the wafer pick-up device 400A places the wafer on the heat sink 200A of the mounting station 310A, multiple lifting columns 342A at the mounting platform 310A pass through the holes on the heat sink 200A and extend upward. The second gripper 410A places the wafer on the lifting columns 342A, and then the lifting columns 342A retract downward and return to the original position, which causes the wafer to move downward until the wafer is attached to the heat sink 200A.

FIG. 15 is a schematic flow chart of a control method of the wafer loading and unloading equipment according to another embodiment of the invention. As shown in FIG. 15, in the embodiment, the control method of the wafer loading and unloading equipment also includes the following steps:
Step S1210, after the wafer completes the wafer-level burn-in test, controlling the wafer transfer device 100A to take out the heat sink 200A carrying the wafer from the wafer-level burn-in test apparatus 610A;
Step S1220, controlling the mounting platform 310A of the heat sink test device 300A to extend out;
Step S1230, controlling the wafer transfer device 100A to place the heat sink 200A carrying the wafer on the mounting platform 310A;
Step S1240, controlling the mounting platform 310A to reset; and
Step S1250, controlling the wafer pick-up device 400A to transfer the wafer from the heat sink 200A to the wafer cassette 500A.

The embodiment not only completes loading of a wafer fully automatically, but also places the wafer back to the wafer cassette 500A fully automatically after the wafer completes the wafer-level burn-in test. The entire wafer loading and unloading process does not require personnel participation, which improves the intelligent level of wafer-level burn-in testing.

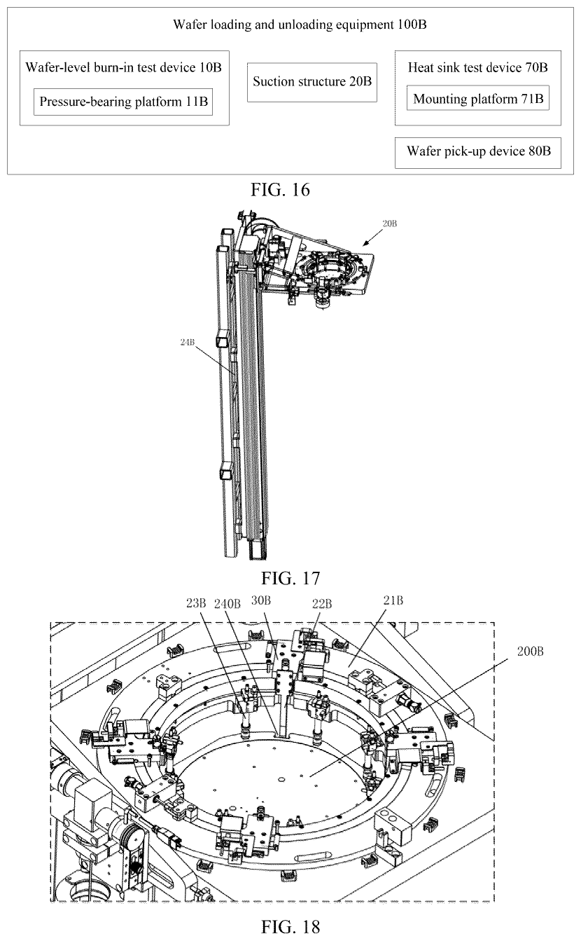

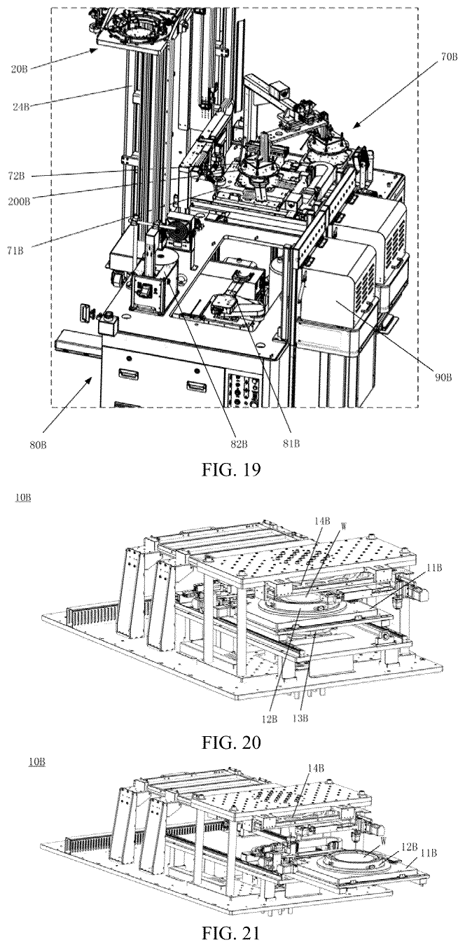

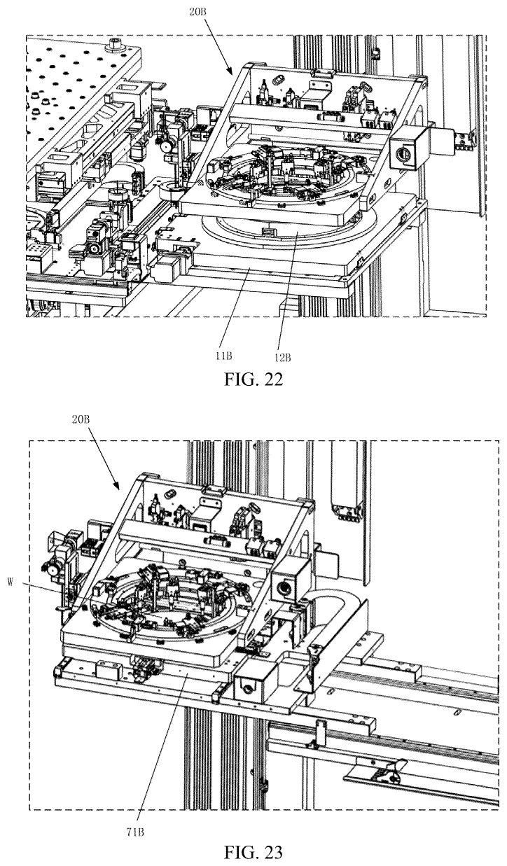

FIG. 16 is a schematic block diagram of a wafer loading and unloading equipment 100B according to an embodiment of the invention. FIG. 17 is a schematic connection diagram of a suction structure 20B and a lifting structure 24B according to an embodiment of the invention. FIG. 18 is a schematic structural diagram of the suction structure 20B according to an embodiment of the invention. FIG. 19 is a schematic structural diagram of a wafer pick-up device 80B and a heat sink test device 70B according to an embodiment of the invention. FIG. 20 is a schematic structural diagram of a pressure-bearing platform 11B of a wafer-level burn-in test device 10B in an original state according to an embodiment of the invention. FIG. 21 is a schematic structural diagram of the pressure-bearing platform 11B of the wafer-level burn-in test device 10B in an extend-out state according to an embodiment of the invention. FIG. 22 is a schematic structural diagram of the suction structure 20B placing a heat sink 200B in a lower sealing cover 12B according to an embodiment of the invention. FIG. 23 is a schematic structural diagram of the suction structure 20B taking out the heat sink 200B from a mounting platform 71B according to an embodiment of the invention. As shown in FIGS. 16-23, in the embodiment, the wafer loading and unloading equipment 100B includes the wafer pick-up device 80B, the heat sink test device 70B, the suction structure 20B, and the wafer-level burn-in test device 10B. The wafer pick-up device 80B is configured to place a target wafer W on the heat sink 200B of the mounting platform 71B of the heat sink test device 70B. The heat sink test device 70B is provided next to the wafer pick-up device 80B and has the mounting platform 71B. The mounting platform 71B is configured to laterally extend out toward the wafer-level burn-in test device 10B or reset in a controlled manner. The suction structure 20B is disposed beside the heat sink test device 70B, and is configured to controllably clamp the heat sink 200B carrying the target wafer W. Further, the suction structure 20B places the heat sink 200B carrying the target wafer W in the lower sealing cover 12B of the pressure-bearing platform 11B of the wafer-level burn-in test device 10B. The wafer-level burn-in test device 10B is arranged next to the suction structure 20B and used to perform a wafer-level burn-in test on the target wafer W. The wafer-level burn-in test device 10B has the pressure-bearing platform 11B. The pressure-bearing platform 11B is configured to extend out laterally toward the heat sink test device 70B or reset in a controlled manner.

In the embodiment, the mounting platform 71B is configured to extend laterally toward the wafer-level burn-in test device 10B and reach a position below the suction structure 20B in a controlled manner. The suction structure 20B is configured to clamp the heat sink 200B after the mounting platform 71B extends out laterally. Then, the suction structure 20B drives the heat sink 200B carrying the target wafer W to move upward to a first target position, and the pressure-bearing platform 11B extends laterally toward the heat sink test device 70B in a controlled manner and extends to a position below the suction structure 20B.

In the embodiment, the suction structure 20B adopts a method of moving up and down to realize the transportation of the heat sink 200B. It is only necessary to control the pressure-bearing platform 11B of the wafer-level burn-in test device 10B and the mounting platform 71B of the heat sink test device 70B to stagger and extend laterally to a place below the suction structure 20B. In some other embodiments, the suction structure 20B may also move left and right to transport the heat sink 200B, which may be set according to design requirements.

In the embodiment, the heat sink test device 70B and the wafer-level burn-in test device 10B are respectively arranged on the left and right sides of the suction structure 20B. It may reduce the transportation distance of the target wafer W and save the transportation time. It also makes the structure of the wafer loading and unloading equipment 100B more compact and taking up less space.

In the embodiment, the wafer-level burn-in test device 10B also includes a lifting structure 13B positioned below the pressure-bearing platform 11B and a cover plate assembly 14B above the pressure-bearing platform 11B. It is arranged that after the lifting structure 13B moves upward to abut the lower sealing cover 12B, the lifting structure 13B continues moving upward, thereby driving the lower sealing cover 12B to move upward to connect with the cover plate assembly 14B to form a test chamber. As such, a wafer-level burn-in test may be performed on the target wafer W in the test chamber.

In the embodiment, the heat sink test device 70B is provided with a gripper (i.e., a first gripper) 72B for sucking the heat sink 200B. When dust is detected on the heat sink 200B, the gripper 72B may move the heat sink 200B to a fan next to the mounting platform 71B for dust cleaning. Thereafter, the cleaned heat sink 200B is placed again on the mounting platform 71B. The mounting platform 71B of the heat sink test device 70B may extend to the left to reach a position below the suction structure 20B. As such, after moving down, the suction structure 20B may take or place the heat sink 200B carrying the target wafer W.

In the embodiment, the wafer pick-up device 80B may have a robot hand (which may be referred to as a second gripper) 81B. The robot hand 81B takes out the target wafer W to be tested from the wafer cassette 90B, and then places the target wafer W on a wafer position calibration station 82B for position calibration. After calibration of the wafer position, the robot hand 81B moves in a direction towards the heat sink test device 70B, and places the target wafer W on the heat sink 200B of the mounting platform 71B of the heat sink test device 70B. After this, the wafer and heat sink 200B may be regarded as one body and transported together during the entire moving process. That is, in the heat sink test device 70B, the suction structure 20B, and the wafer-level burn-in test device 10B, the heat sink 200B and the target wafer W may be regarded as one body and transported together.

In the embodiment, the suction structure 20B is connected to the lifting structure 24B, and the lifting mechanism 24B may drive the suction structure 20B to move vertically. The suction structure 20B includes a first bracket 21B, multiple suction members 23B, and multiple snap-in parts 22B. The first bracket 21B is ring-shaped. The suction members 23B are arranged at intervals along the circumferential direction of the first bracket 21B and are connected to the first bracket 21B. Multiple suction members 23B are arranged to provide suction forces to the bottom of the target wafer W concurrently, so that the target wafer W is attached to the heat sink 200B. Multiple snap-in parts 22B are arranged at intervals along the circumferential direction of the first bracket 21B and connected to the first bracket 21B. The snap-in parts 22B are arranged to clamp and suck the heat sink 200B carrying the target wafer W simultaneously in a controlled manner, preventing the heat sink 200B carrying the target wafer W from falling off during movements. The suction members 23B and snap-in parts 22B are arranged in a staggered manner. The snap-in parts 22B and suction members 23B are evenly arranged on the first bracket 21B. The lifting structure 24B may drive the suction structure 20B to move up and down.

In the embodiment, sucking the bottom of the target wafer W through multiple suction members 23B makes the target wafer W attached to the heat sink 200B, which prevents the target wafer W from moving and falling off. In addition, the heat sink 200B carrying the target wafer W is simultaneously clamped through multiple snap-in parts 22B. The snap-in parts 22B also provide suction forces on the heat sink 200B, thereby preventing the heat sink 200B from falling off during transportation and improving the movement stability of the heat sink 200B. In the invention, not only the target wafer W is sucked, but also the heat sink 200B is sucked. By double suction, it may ensure the stability of the target wafer W and heat sink 200B during transportation, and prevent the target wafer W and heat sink 200B from falling off the suction structure 20B.

As shown in FIG. 18, in the embodiment, the wafer loading and unloading equipment 100B also includes multiple sliding components 30B. Each sliding component 30B corresponds to a snap-in part 22B, and is used to connect the snap-in part 22B with the first bracket 21B with sliding connection. Thus, the snap-in part 22B may slide along the radial direction of the first bracket 21B in a controlled manner, thereby switching between a first position of clamping the heat sink 200B and a second position of separation from the heat sink 200B. It can be understood that all sliding components 30B simultaneously drive the snap-in parts 22B to move toward the center of the first bracket 21B for supporting the heat sink 200B concurrently. At this time, the snap-in part 22B is in the first position. When all the sliding components 30B simultaneously drive corresponding snap-in parts 22B to return to their original positions, that is, when moving away from the center position of the first bracket 21B, the support for heat sink 200B is withdrawn. At this time, the snap-in part 22B is in the second position.

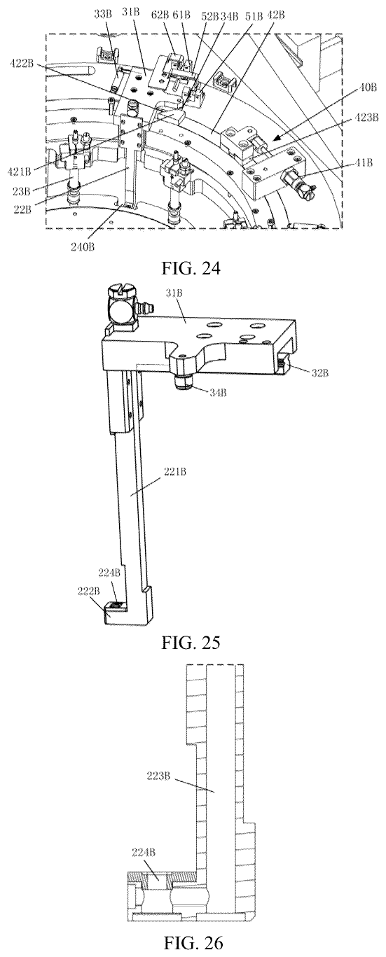

FIG. 24 is a schematic partial view of the suction structure 20B according to an embodiment of the invention. FIG. 25 is a schematic structural view of the snap-in part 22B and the sliding component 30B according to an embodiment of the invention. FIG. 26 is a schematic cross-sectional view of the snap-in part 22B according to an embodiment of the invention. As shown in FIGS. 24-26 and referring to FIG. 18, the snap-in part 22B is L-shaped and has a vertical part 221B and a horizontal part 222B. The horizontal part 222B is configured to abut the bottom of the heat sink 200B when the snap-in 22B moves toward the center direction of the first bracket 21B to support the heat sink 200B. As shown in FIG. 24, multiple notches 240B are provided on the peripheral side of the heat sink 200B, and each notch 240B corresponds to a snap-in part 22B. The snap-in part 22B moves from the notch 240B until the horizontal part 222B is below the heat sink 200B. At this position, the snap-in part 22B may support the heat sink 200B. When the horizontal part 222B of the snap-in part 22B moves to the notch 240B, its support for the heat sink 200B is removed.

In the embodiment, a first air channel 223B is provided inside the snap-in part 22B. When abutting the bottom of the heat sink 200B, the snap-in part 22B sucks the heat sink 200B. As shown in FIG. 25, the top of the horizontal part 222B has a suction mouth 224B connected to the first air channel 223B. The heat sink 200B is sucked through the suction mouth 224B. In the embodiment, not only the target wafer W is sucked, but also the bottom of the heat sink 200B is sucked. It may prevent the heat sink 200B from moving or slipping off.

As shown in FIG. 24, in the embodiment, the wafer loading and unloading equipment 100B also includes a drive assembly 40B. The drive assembly 40B is disposed on the first bracket 21B and cooperates with multiple snap-in parts 22B and sliding components 30B, simultaneously driving the snap-in parts 22B to switch between the first position and the second position in a controlled manner. That is, the drive assembly 40B may drive multiple sliding components 30B at the same time to drive corresponding snap-in parts 22B to move.

In the embodiment, the drive assembly 40B includes at least one first power source 41B and an annular connector 42B. The first power source 41B is installed on the top of the first bracket 21B. The annular connector 42B is installed on the first bracket 21B and arranged concentrically with the first bracket 21B. The annular connector 42B is connected to the first power source 41B and cooperates with multiple sliding components 30B. The annular connector 42B is configured to rotate when driven by the first power source 41B, which simultaneously drives multiple sliding components 30B to slide, thereby driving multiple snap-in parts 22B to move at the same time. The first power source 41B is a pen-type cylinder. In some other embodiments, the first power source 41B may also employ other components, such as a rack and pinion structure. In the embodiment, the number of the first power source 41B is two, and the two first power sources 41B are spaced apart on the first bracket 21B. In some other embodiments, the number of the first power source 41B may also be set according to specific design requirements. For example, the number of the first power source 41B may be set according to the diameter of the annular connector 42B. The larger the diameter of the annular connector 42B, the greater the number of the first power source 41B. The smaller the diameter of the annular connector 42B, the smaller the number of the first power source 41B.

Referring to FIGS. 24 and 25, in the embodiment, the sliding component 30B includes an upper sliding part 31B connected to the snap-in part 22B and a lower sliding part 32B connected to the first bracket 21B. The upper sliding part 31B is provided with a contact portion 34B. The annular connector 42B is provided with multiple first protrusions 421B with inclined surfaces 422B. Each first protrusion 421B corresponds to a contact portion 34B of the sliding component 30B. The first protrusion 421B is configured to cause the contact portion 34B to slide along the inclined surface 422B during the rotation of the annular connector 42B, thereby driving the upper sliding part 31B to slide along the lower sliding part 32B. That is, during the rotation of the annular connector 42B, the first protrusion 421B is made to move. At this time, the contact portion 34B may move upward or downward along the inclined surface 422B. When the annular connector 42B rotates clockwise, the contact portion 34B moves downward along the inclined surface 422B, and the upper sliding part 31B drives the snap-in part 22B to move toward the center of the first bracket 21B until the snap-in part 22B reaches the first position.

When the annular connector 42B rotates counterclockwise, the contact portion 34B moves upward along the inclined surface 422B, and the upper sliding part 31B drives the snap-in part 22B to move away from the center of the first bracket 21B until the snap-in part 22B reaches the second position. In the embodiment, by ingeniously arranging the protrusions with the inclined surface 422B, the movement of the snap-in part is realized. It has a simple structure and is easy to implement. The annular connector 42B is also provided with multiple second protrusions 423B. Each second protrusion 423B is provided with a groove, and connected with a connecting piece that matches the groove. The connecting piece is connected to the first power source 41B, so that the first power source 41B drives the annular connector 42B to rotate through the cooperation of the connecting piece and the second protrusion 423B. In the embodiment, one end of the upper sliding part 31B is also connected to the first bracket 21B through an elastic member 33B. When the snap-in part 22B is at the second position, the elastic member 33B is in a stretched state. When the snap-in part 22B is at the first position, the elastic member 33B restores to its original state.

Referring to FIG. 18, the wafer loading and unloading equipment 100B also includes multiple first sensors 51B and multiple second sensors 61B. The first sensor 51B is installed on the first bracket 21B. Each first sensor 51B corresponds to a sliding component 30B and is used to detect whether a corresponding snap-in part 22B is in the first position. The second sensor 61B is installed on the first bracket 21B. Each second sensor 61B corresponds to a sliding component 30B and is used to detect whether a corresponding snap-in part 22B is in the second position. It can be understood that each sliding component 30B is configured with a first sensor 51B and a second sensor 61B. The upper sliding part 31B of the sliding component 30B is connected with a first limiting part 52B and a second limiting part 62B. The first limiting part 52B is used to cooperate with the first sensor 51B, and the second limiting part 62B is used to cooperate with the second sensor 61B. When the first sensor 51B senses the first limiting part 52B, it indicates that the snap-in part 22B reaches the first position. When the second sensor 61B senses the second limiting part 62B, it indicates that the snap-in part 22B reaches the second position.

In the embodiment, the wafer loading and unloading equipment 100B also includes a controller (not shown). The controller is respectively connected to multiple suction members 23B, the first power source 41B, the first sensor 51B, and the second sensor 61B. The controller makes the sliding component 30B to drive the snap-in part 22B to move, thereby causing the snap-in part 22B to clamp the heat sink 200B. When multiple suction members 23B feedback contacting with the heat sink 200B concurrently, it indicates the heat sink 200B is in a horizontal state, not tilted, and there is no need to adjust the position of the heat sink 200B. Thus, multiple snap-in parts 22B may be directly controlled to clamp the heat sink 200B. It prevents the heat sink 200B from slipping off due to unstable clamping state when the heat sink 200B is tilted. The clamping stability of the heat sink 200B is improved.

In the embodiment, after receiving feedback signals from multiple suction members 23B at the same time and the feedback signals indicate that suction members 23B are in contact with the heat sink 200B, the controller is configured to control the first power source 41B to drive the annular connector 42B to move in the circumferential direction of the first bracket 21B. The controller is also configured to control the snap-in parts 22B to suck the heat sink 200B after receiving signals fed back by the first sensor 51B. Thereafter, the controller is configured to control the lifting structure 24B to drive the suction structure 20B to move vertically. The controller is also configured to control the lifting structure 24B to drive the suction structure 20B to move vertically after receiving feedback signals from the second sensor 61B.

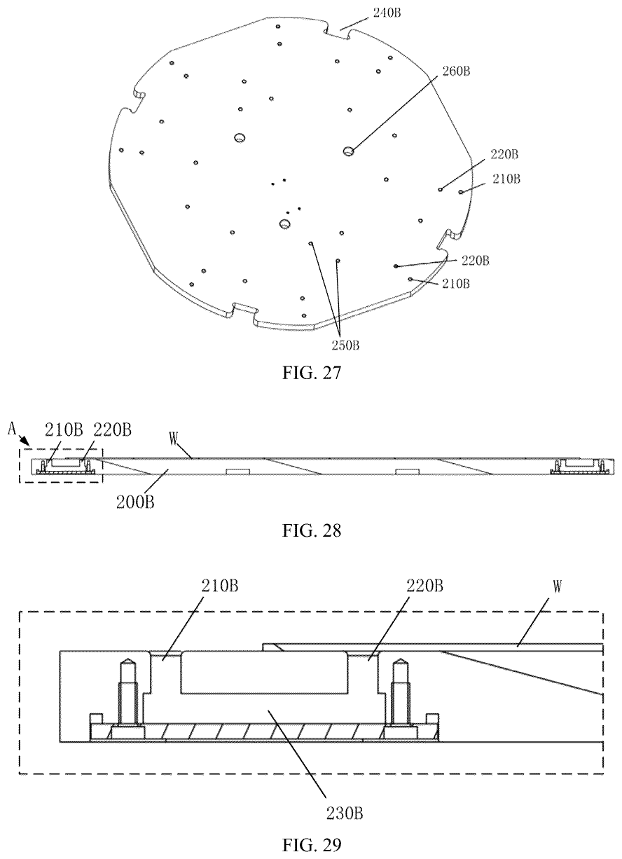

FIG. 27 is a schematic structural diagram of the heat sink 200B according to an embodiment of the invention. FIG. 28 is a schematic cross-sectional view of the heat sink 200B according to an embodiment of the invention. FIG. 29 is a schematic enlarged view of a part A in FIG. 28. As shown in FIG. 27-29, in the embodiment, multiple second air channels 230B are provided inside the heat sink 200B. Each second air channel 230B corresponds to a suction member 23B. The second air channel 230B contains a first air hole 220B and a second air hole 210B disposed on the top of the heat sink 200B. As shown in FIG. 29, the target wafer W is positioned on top of the first air hole 220B when the target wafer W is on the heat sink 200B.

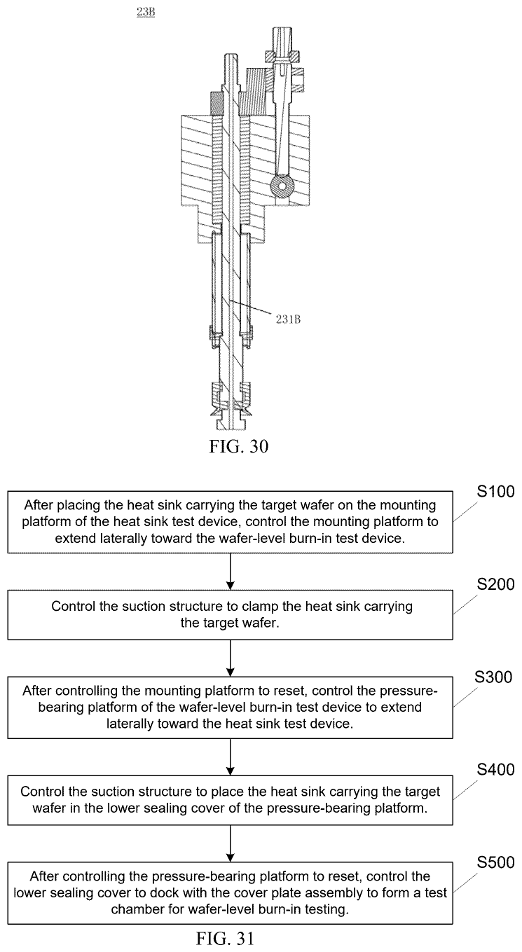

FIG. 30 is a schematic cross-sectional view of the suction member 23B according to an embodiment of the invention. As shown in FIG. 30 and referring to FIG. 18, a third air channel 231B is provided inside the suction member 23B and extends downward from the first bracket 21B. The third air channel 231B is arranged to communicate with the second air hole 210B of a corresponding second air channel 230B, when the suction member 23B abuts the heat sink 200B. As such, the target wafer W is sucked through the second air hole 210B, the second air channel 230B, and the first air hole 220B sequentially. In the embodiment, the number of the second air channel 230B is eight, and each second air channel 230B corresponds to one suction member 23B. In some other embodiments, the number of the second air channel 230B may be set according to actual needs.

In the embodiment, the heat sink 200B also has a first vacuum suction air channel 250B and a through hole 260B arranged along the thickness direction. The first vacuum suction air channel 250B is used to vacuum from the bottom to suck a target wafer W on the top of the heat sink 200B. The through hole 260B is used for the second bracket to pass through the heat sink 200B to receive the target wafer W.

FIG. 31 is a schematic flow chart of a control method of a wafer loading and unloading equipment according to an embodiment of the invention. As shown in FIG. 31, in a specific embodiment, the control method of the wafer loading and unloading equipment includes the following steps:
Step S100, after placing the heat sink 200B carrying the target wafer W on the mounting platform 71B of the heat sink test device 70B, controlling the mounting platform 71B to extend laterally toward the wafer-level burn-in test device 10B;
Step S200, controlling the suction structure 20B to clamp the heat sink 200B carrying the target wafer W;
Step S300, after controlling the mounting platform 71B to reset, controlling the pressure-bearing platform 11B of the wafer-level burn-in test device 10B to extend laterally toward the heat sink test device 70B;
Step S400, controlling the suction structure 20B to place the heat sink 200B carrying the target wafer W in the lower sealing cover 12B of the pressure-bearing platform 11B; and
Step S500, after controlling the pressure-bearing platform 11B to reset, controlling the lower sealing cover 12B to dock with the cover plate assembly 14B to form a test chamber for wafer-level burn-in testing.

In the embodiment, transfer of the heat sink 200B is realized by the mounting platform 71B of the heat sink test device 70B and the pressure-bearing platform 11B of the wafer-level burn-in test device 10B respectively extending out laterally combined with the movement of the suction structure 20B. It simplifies wafer loading steps, shortens the wafer transfer distance, and makes the loading equipment more compact.

In the embodiment, the suction structure 20B adopts the method of moving up and down to realize transportation of the heat sink 200B. It is only needed to control the pressure-bearing platform 11B of the wafer-level burn-in test device 10B and the mounting platform 71B of the heat sink test device 70B to stagger and extend laterally to the bottom of the suction structure 20B. In some other embodiments, the suction structure 20B may move left and right to realize transportation of the heat sink 200B, which may be set according to design requirements.

In some embodiments, Step S200 specifically includes the following steps:
Step S210, after it is determined that any snap-in part 22B of the suction structure 20B is in an open state, controlling the suction structure 20B to move downward;
Step S220, controlling any suction member 23B of the suction structure 20B to suck the target wafer W;
Step S230, controlling any snap-in part 22B to clamp the heat sink 200B; and
Step S240, controlling any snap-in part 22B to suck the heat sink 200B.

In the embodiment, the suction structure 20B not only clamps the heat sink 200B carrying the target wafer W, but also sucks the target wafer W and the heat sink 200B at the same time. It improves the stability of the heat sink 200B carrying the target wafer W during transfer processes, and prevents the target wafer W from falling off, curling, or being damaged during transportation.

In a preferred embodiment, before the suction structure 20B moves downward, all snap-in parts 22B are controlled to open. Photoelectric sensors of each snap-in part 22B of the suction structure 20B obtain information on whether the snap-in parts 22B are in an open state. If it is determined that all the snap-in parts 22B are in the open state, the suction structure 20B is controlled to move downward. If any snap-in part 22B is not opened, an alarm is issued. In the embodiment, the snap-in part 22B may be considered as a claw. During Step S240, the interior of the snap-in part 22B is provided with an air channel connected to a vacuum suction equipment. Vacuuming is performed by turning on the vacuum suction equipment, thereby sucking the heat sink 200B. The snap-in part 22B may suck the bottom of the heat sink 200B.

In some embodiments, Step S220 includes the following steps:
Step S221, during a downward movement of the suction structure 20B, it is determined whether all suction members 23B of the suction structure 20B are in contact with the heat sink 200B. If yes, Step S222 is executed. If not, the suction structure 20B is controlled to continue to move downward until it contacts the heat sink 200B;
Step S222, after the suction structure 20B is controlled to continue to move downward a first preset distance, the suction members 23B are controlled to attach the target wafer W to the heat sink 200B by suction. The first preset distance may be determined according to specific design requirements.

During Step S221, the suction member 23B feeds back contact signals. That is, a contact switch is configured on the suction member 23B. If the contact switch comes into contact with the heat sink 200B, the contact switch is turned on. If there is no contact, the contact switch is off. Thus, whether the suction member 23B is in contact with the heat sink 200B is determined according to the contact signal.

During Step S222, the inside of the suction member 23B is provided with an air channel connected to the vacuum suction equipment. Through turning on the vacuum suction equipment to vacuum, the target wafer W is sucked. The suction member 23B is aligned with the second air hole 210B of the second air channel 230B of the heat sink 200B. The target wafer W is sucked through the second air hole 210B, the second air channel 230B, and the first air hole 220B sequentially. At this time, the target wafer W is positioned above the first air hole 220B of the heat sink 200B. Based on obtained vacuum level information of each suction member 23B, it is determined whether each suction member 23B sucks the target wafer W. If it is determined that each suction member 23B sucks the target wafer W, Step S230 is performed.

In some embodiments, Step S230 includes the following steps:
Step S231, controlling any snap-in part 22B to move toward the centerline of the suction structure 20B and reach a corresponding second target position;
Step S232, determining whether any snap-in part 22B reaches its corresponding second target position; if so, performing Step S233; and if not, issuing an alarm; and
Step S233, controlling the snap-in parts 22B to move upward a second preset distance, and causing the free end of any snap-in part 22B to contact the bottom of the heat sink 200B to clamp the heat sink 200B.

During Step S231, after moving toward the centerline of the suction structure 20B, the snap-in part 22B hooks the heat sink 200B from the bottom of the heat sink 200B. The edge of the heat sink 200B has multiple notches 240B. The snap-in part 22B moves from the notch 240B until part of the snap-in part 22B is below the heat sink 200B. That is, the snap-in part 22B moves toward the centerline direction of the suction structure 20B. Then, the snap-in part 22B may support the heat sink 200B.

During Step S232, the photoelectric sensor on each snap-in part 22B scans the position of the snap-in part 22B, and it is determined whether the snap-in part 22B reaches the second target position. If no signal is detected, it indicates that the snap-in part 22B may be interfered by the heat sink 200B, and an alarm signal is generated.

During Step S233, the second preset distance is any value in the range of 0.5 mm˜1 mm. For example, the second preset distance may be 0.5 mm, 0.7 mm, or 1 mm, which ensures that the snap-in part 22B abuts the bottom of the heat sink 200B.

In the embodiment, Step S240 also includes the following steps:
Step S241, controlling any snap-in part 22B to suck the bottom of the heat sink 200B;
Step S242, obtaining vacuum level information of the vacuum suction equipment connected to any snap-in part 22B;
Step S243, determining whether a corresponding snap-in part 22B sucks the heat sink 200B according to the vacuum level information; if so, executing Step S244; if not, issuing an alarm; and
Step S244, controlling the suction structure 20B to drive the heat sink 200B carrying the target wafer W to move upward to the first target position.

During Step S241, the first air channel 223B is provided inside the snap-in part 22B, so that the snap-in part 22B sucks the heat sink 200B when abutting the bottom of the heat sink 200B. As shown in FIG. 25, the top of the horizontal part 222B has a suction mouth 224B connected with the first air channel 223B, and the heat sink 200B is sucked through the suction mouth 224B. In the embodiment, not only the target wafer W is sucked, but also the bottom of the heat sink 200B is sucked. It prevents the heat sink 200B from moving or slipping off.

During Step S243, the stability of the heat sink 200B during transportation is ensured by judging the vacuum level.

In some embodiments, before Step S100 is performed, the control method further includes the following steps:
Step S10, obtaining position information of the target wafer W in the wafer cassette 90B;
Step S20, according to the position information, controlling the wafer pick-up device 80B to grasp the target wafer W and transfer it to a wafer position calibration station to adjust the angle and eccentricity of the target wafer W; and
Step S30, controlling the wafer pick-up device 80B to transfer the adjusted target wafer W from the wafer position calibration station to the heat sink test device 70B.

During Step S10, a scanning device scans the placement of the target wafer W in the wafer cassette 90B and obtains the position of the target wafer W in the wafer cassette 90B. The layer where the target wafer W is placed in the wafer cassette 90B and whether the target wafer W is placed horizontally are determined. Because the target wafer W is manually placed in the wafer cassette 90B, the wafer may be placed tilted. If it is recognized that the target wafer W is not placed horizontally in the wafer cassette 90B, an alarm signal is sent out.

During Step S20, the robot hand 81B of the wafer pick-up device 80B supports the target wafer W at a position below the target wafer W, and picks up the wafer by sucking the lower surface of the wafer. Before controlling the robot hand 81B to take out the target wafer W from the wafer cassette 90B, the vacuum level needs to be detected to determine whether the robot hand 81B sucks the wafer. It prevents the target wafer W from falling off during moving processes and ensures the stability of the target wafer W during transportation. In the embodiment, the angle adjustment and eccentricity adjustment of the target wafer W may be performed as follows: adjusting the angle after finding the tilt angle and center of the target wafer W through a camera device, and then adjusting the position along the X and Y directions.

In the embodiment, Step S100 specifically includes the following steps:
Step S110, after the second bracket that has passed through the heat sink 200B in advance receives the target wafer W, controlling to the second bracket to go downward and separate from the heat sink 200B, so that the target wafer W attaches to the heat sink 200B;
Step S120, sucking the target wafer W by vacuuming through the first vacuum suction air channel 250B in the heat sink 200B;
Step S130, determining whether the target wafer W is attached to the heat sink 200B by suction and in a preset area of the heat sink 200B; if so, executing Step S140; if not, controlling the wafer pick-up device 80B to retrieve the target wafer W, and re-executing Step S110; and
Step S140, controlling the mounting platform 71B to extend laterally toward the heat sink test device 70B until part of the mounting platform 71B reaches a position below the suction structure 20B of the wafer transfer device.

During Step S110, as the heat sink 200B has through holes 260B extending along the thickness direction, when the second bracket passes through the through holes 260B and rises above the heat sink 200B, the target wafer W is directly places on the second bracket. Then the second bracket moves downward, and the target wafer W is lowered and placed on the heat sink 200B. After that, the second bracket continues to descend and becomes separated from the through holes 260B, thereby being separated from the heat sink 200B.

During Step S120, as shown in FIG. 27, the first vacuum suction air channels 250B show up as air holes. One air hole of the first vacuum suction air channel 250B is located on the upper surface of the heat sink 200B, and the other air hole is located on the lower surface of the heat sink 200B. Vacuuming is performed through the air hole on the lower surface and the first vacuum suction air channel 250B. The target wafer W is attached to the heat sink 200B by vacuum suction created. That is, at least two air channels are configured inside the heat sink 200B. One air channel, i.e., the second air channel 230B, is used for suction by the suction structure 20B and provided at the edge of the heat sink 200B. Another air channel, i.e., the first vacuum suction air channel 250B, is arranged along the thickness direction of the heat sink 200B, and used for the vacuum suction structure to suck the target wafer W, when the heat sink 200B and target wafer W are on the mounting platform 71B.

During Step S130, whether the wafer is sucked on the heat sink 200B is determined by the vacuum level. If the edge of the target wafer W is not in the preset area of the heat sink 200B, or the target wafer W is seriously warped, position deviation may occur.

During Step S140, the lateral movement distance of the mounting platform 71B is set according to specific design requirements. Steps S140 and S210 may be performed simultaneously.

In some embodiments, Step S300 specifically includes the following steps:
Step S310, after controlling the mounting platform 71B to reset, controlling the second vacuum suction air channel in the pressure-bearing platform 11B to suck the lower sealing cover 12B;
Step S320, determining whether the lower sealing cover 12B is sucked according to vacuum level information of the second vacuum suction air channel; if yes, executing Step S330; if not, issuing an alarm; and
Step S330, controlling the pressure-bearing platform 11B of the wafer-level burn-in test device 10B to extend laterally toward the heat sink test device 70B until reaching a position below the suction structure 20B.

During Step S320, since the lower sealing cover 12B is positioned and installed on the pressure-bearing platform 11B through positioning pins, but the positioning pin may have abnormal situations, it is necessary to determine the placement position of the lower sealing cover 12B again based on the vacuum level. It prevents the lower sealing cover 12B from slipping off or shifting during the lateral movement of the pressure-bearing platform 11B.

In the embodiment, Step S400 further includes the following steps:
Step S410, sucking the heat sink 200B and target wafer W respectively by vacuuming via the second vacuum suction air channel in the pressure-bearing platform 11B;
Step S420, withdrawing the clamp on the heat sink 200B carrying the target wafer W by the snap-in part 22B; and
Step S430, controlling the suction structure 20B to reset.

In the embodiment, the suction force of the snap-in part 22B on the heat sink 200B and the suction force of the suction member 23B on the target wafer W are removed, after the pressure-bearing platform 11B sucks the heat sink 200B and target wafer W. It ensures that the heat sink 200B and target wafer W are always sucked during transportation processes. There is no interruption of the suction force. Thus, warping of the target wafer W may not occur.

During Step S410, the second vacuum suction air channel in the pressure-bearing platform 11B not only sucks the lower sealing cover 12B, but also sucks the target wafer W, when the heat sink 200B and target wafer W are in the lower sealing cover 12B, and the second vacuum suction air channel is connected to the first vacuum suction air channel 250B of the heat sink 200B.

In the embodiment, Step S500 specifically includes the following steps:
Step S510, controlling the pressure-bearing platform 11B to reset;
Step S520, obtaining position information of the target wafer W;
Step S530, making coupling alignment between the target wafer W and a test probe according to the position information of the target wafer W and adjusting the position of the target wafer W; and
Step S540, controlling the lifting structure 13B to move the lower sealing cover 12B upward to connect with the upper cover plate assembly, and form a test chamber for performing wafer-level burn-in tests on the target wafer W.

During Step S530, the target wafer W is photographed twice by a photographing device, and the tilt angle of the target wafer W is calculated through a connection line between two chips. Thereafter, the angle of the target wafer W is adjusted, and then alignment in the X direction and Y direction is performed.

In some embodiments, after Step S500, the control method further includes the following steps:
Step S610, controlling the lower sealing cover 12B to separate from the cover plate assembly 14B and lowering the lower sealing cover 12B to reach the pressure-bearing platform 11B;
Step S620, controlling the pressure-bearing platform 11B to extend laterally toward the heat sink test device 70B;
Step S630, controlling the suction structure 20B to take out the heat sink 200B carrying the target wafer W from the lower sealing cover 12B;
Step S640, controlling the pressure-bearing platform 11B to reset;
Step S650, controlling the mounting platform 71B of the heat sink test device 70B to extend laterally toward the wafer-level burn-in test device 10B;
Step S660, controlling the suction structure 20B to place the heat sink 200B carrying the target wafer W on the mounting platform 71B;
Step S670, controlling the mounting platform 71B to reset; and
Step S680, controlling the wafer pick-up device 80B to transfer the wafer from the heat sink 200B to the wafer cassette 90B.

In the embodiment, after the target wafer W completes the wafer-level burn-in test, the lifting structure 13B is controlled to drive the lower sealing cover 12B to move downward to reset. Then, the pressure-bearing platform 11B is controlled to extend laterally toward the heat sink test device 70B and reach a position below the suction structure 20B.

In the embodiment, a fully automated wafer loading and unloading equipment is designed. The heat sink 200B and target wafer W may be quickly and easily transferred to the wafer-level burn-in test device 10B. It has a high degree of automation, high feeding reliability, and is highly convenient to use. In addition, the equipment structure is simple and compact, and the space utilization is effectively improved.

By now, those skilled in the art should appreciate that, although a number of exemplary embodiments of the present invention have been shown and described in detail herein, without departing from the spirit and scope of the present invention, many other variations or modifications consistent with the principles of the present invention can still be directly determined or deduced from the disclosure of the present invention. Accordingly, the scope of the present invention should be understood and deemed to cover all such other variations or modifications.

1. A wafer transfer device used for transferring a heat sink carrying a wafer, the wafer transfer device including a suction structure and a lifting structure capable of driving the suction structure to move vertically, the suction structure comprising:
a first bracket being ring-shaped and connected to the lifting structure;
a plurality of suction members arranged at intervals along a circumferential direction of the first bracket, connected to the first bracket, and configured to provide suction forces to a bottom of the wafer concurrently for attaching the wafer to the heat sink; and
a plurality of snap-in parts arranged at intervals along the circumferential direction of the first bracket, connected to the first bracket, configured to be controlled to clamp the heat sink carrying the wafer concurrently, and providing suction forces on the heat sink to prevent the heat sink carrying the wafer from falling off while the heat sink moves with the suction structure in a movement.

2. The device according to claim 1, further comprising:
a plurality of sliding components, wherein each sliding component corresponds to one of the plurality of snap-in parts and is used to connect the one of the plurality of snap-in parts to the first bracket with sliding connection, so that the one of the plurality of snap-in parts controllably slides along a radial direction of the first bracket, and switches between a first position of clamping the heat sink and a second position of separation from the heat sink.

3. The device according to claim 2, wherein the one of the plurality of snap-in parts is L-shaped and has a vertical part and a horizontal part, the horizontal part is configured to abut a bottom of the heat sink to support the heat sink when the one of the plurality of snap-in parts moves toward a center direction of the first bracket, and a first air channel is provided inside the one of the plurality of snap-in parts to suck the heat sink when the one of the plurality of snap-in parts abuts the bottom of the heat sink.

4. The device according to claim 3, further comprising:
a drive assembly arranged on the first bracket and cooperating with more than one of the plurality of sliding components to simultaneously drive the one of the plurality of snap-in parts to switch between the first position and the second position in a controlled manner.

5. The device according to claim 4, wherein the drive assembly includes:
at least one first power source installed on a top of the first bracket; and
an annular connector installed on the first bracket and arranged concentrically with the first bracket, wherein the annular connector is connected to the at least one first power source and cooperates with the more than one of the plurality of sliding components, the annular connector is configured to rotate when being driven by the at least one first power source to simultaneously drive the more than one of the plurality of sliding components to slide to simultaneously drive more than one of the plurality of snap-in parts to move.

6. The device according to claim 5, wherein the plurality of sliding components includes an upper sliding part connected to the one of the plurality of snap-in parts and a lower sliding part connected to the first bracket, the upper sliding part is provided with a contact portion, the annular connector is provided with a plurality of first protrusions with inclined surfaces, each protrusion corresponds to one of contact portions of the plurality of sliding components, the plurality of first protrusions is configured to cause the contact portions to slide along the inclined surfaces during rotation of the annular connector to drive the upper sliding part to slide along the lower sliding part, and wherein the device further comprises:
a plurality of first sensors installed on the first bracket, wherein each first sensor corresponds to one of the plurality of sliding components and is used to detect whether a corresponding snap-in part is in the first position;
a plurality of second sensors installed on the first bracket, wherein each second sensor corresponds to one of the plurality of sliding components and is used to detect whether a corresponding snap-in part is in the second position; and
a controller connected to the plurality of suction members, the at least one first power source, the first sensor, and the second sensor, respectively, wherein the controller is configured to control the at least one first power source to drive the annular connector to move along the circumferential direction of the first bracket after receiving concurrently from more than one of the plurality of suction members feedback signals that the more than one of the plurality of suction members are in contact with the heat sink, the controller is further configured to control the plurality of snap-in parts to suck the heat sink and then control the lifting structure to drive the suction structure to move vertically after receiving a feedback signal from the first sensor, and the controller is further configured to control the lifting structure to drive the suction structure to move vertically after receiving a feedback signal from the second sensor.

7. (canceled)

8. (canceled)

9. The device according to claim 1, wherein a top of the heat sink is provided with a first area for placing the wafer and a second area that includes regions of the top other than the first area, a plurality of second air channels are provided inside the heat sink, and each second air channel corresponds to one of the plurality of suction members and has a first air hole in the first area and a second air hole in the second area, a third air channel is provided inside the one of the plurality of suction members and extends downward from the first bracket, and the third air channel is configured to communicate with the second air hole of the second air channel when the one of the plurality of suction members abuts the heat sink.

10. A wafer loading and unloading equipment, comprising:
a wafer transfer device; a heat sink test device; and
a wafer pick-up device,
wherein the wafer transfer device is used for transferring a heat sink carrying a wafer and placing the heat sink carrying the wafer in a test chamber of a wafer-level burn-in test device or taking it out from the test chamber, the wafer transfer device includes a suction structure and a lifting structure capable of driving the suction structure to move vertically, the suction structure comprises:
a first bracket being ring-shaped and connected to the lifting structure;
a plurality of suction members arranged at intervals along a circumferential direction of the first bracket, connected to the first bracket, and configured to provide suction forces to a bottom of the wafer concurrently for attaching the wafer to the heat sink; and
a plurality of snap-in parts arranged at intervals along the circumferential direction of the first bracket, connected to the first bracket, configured to be controlled to clamp the heat sink carrying the wafer concurrently, and providing suction forces on the heat sink to prevent the heat sink carrying the wafer from falling off while the heat sink moves with the suction structure in a movement,
wherein the heat sink test device is provided beside the wafer transfer device and has a mounting platform for placing the heat sink, the mounting platform is configured to controllably extend out of the heat sink test device for the wafer transfer device to place the heat sink carrying the wafer on the mounting platform or take out the heat sink carrying the wafer from the mounting platform,
wherein the wafer pick-up device is configured next to the heat sink test device, and arranged to take out the wafer from a wafer cassette, perform position calibration of the wafer, and then place the wafer on the heat sink at the mounting platform, and the wafer pick-up device is further configured to take the wafer on the heat sink and transfer the wafer to the wafer cassette.

11. The equipment according to claim 10, wherein the mounting platform includes a second bracket that goes up or down in a vertical direction, the second bracket is raised through the heat sink to receive the wafer when the wafer is placed on the mounting platform, and the second bracket is lowered to separate from the heat sink to attach the wafer to the heat sink when the wafer is being transported.

12. A method for controlling a wafer loading and unloading equipment, comprising:
after placing a heat sink carrying a target wafer on a mounting platform of a heat sink test device, controlling the mounting platform to extend laterally toward a wafer-level burn-in test device;
controlling a suction structure to clamp the heat sink carrying the target wafer;
after the mounting platform is controlled to reset, controlling a pressure-bearing platform of the wafer-level burn-in test device to extend laterally toward the heat sink test device;
controlling the suction structure to place the heat sink carrying the target wafer in a lower sealing cover of the pressure-bearing platform; and
after the pressure-bearing platform is controlled to reset, controlling the lower sealing cover to duck with a cover plate assembly to form a test chamber for wafer-level burn-in testing.

13. The method according to claim 12, wherein controlling the suction structure to clamp the heat sink carrying the target wafer includes:
after confirming that any snap-in part of the suction structure is in an open state, controlling the suction structure to move downward;
controlling any suction member of the suction structure to suck the target wafer;
controlling any snap-in part to clamp the heat sink; and
controlling any snap-in part to suck the heat sink.

14. The method according to claim 13, wherein controlling any suction member to suck the target wafer includes:
during a downward movement of the suction structure, determining whether all suction members of the suction mechanism are in contact with the heat sink; and
if it is determined all suction members of the suction mechanism are in contact with the heat sink, after controlling the suction structure to continue to move downward a first preset distance, controlling the suction members to attach the target wafer to the heat sink by suction.

15. The method according to claim 13, wherein controlling any snap-in part to clamp the heat sink includes:
controlling any snap-in part to move toward a centerline of the suction structure and reach a corresponding second target position;
determining whether any snap-in part reaches the corresponding second target position; and
if it is determined any snap-in part reaches the corresponding second target position, controlling any snap-in part to move upward a second preset distance to make a free end of any snap-in part contacting a bottom of the heat sink to clamp the heat sink.

16. The method according to claim 13, wherein controlling any snap-in part to suck the heat sink includes:
controlling any snap-in part to suck a bottom of the heat sink;
obtaining vacuum level information of a vacuum suction equipment connected to any snap-in part;
determining whether corresponding snap-in parts suck the heat sink according to the vacuum level information; and
if the corresponding snap-in parts suck the heat sink, controlling the suction structure to drive the heat sink carrying the target wafer to move upward to reach a first target position.

17. The method according to claim 12, wherein after placing the heat sink carrying the target wafer on the mounting platform of the heat sink test device, and before controlling the mounting platform to extend laterally toward the wafer-level burn-in test device, the method further comprises:
obtaining position information of the target wafer in a wafer cassette;
controlling a wafer pick-up device to grasp the target wafer according to the position information and transfer the target wafer to a wafer position calibration station to adjust an angle and eccentricity of the target wafer; and
controlling the wafer pick-up device to transfer the adjusted target wafer from the wafer position calibration station to the heat sink test device.

18. The method according to claim 12, wherein placing the heat sink carrying the target wafer on the mounting platform of the heat sink test device and controlling the mounting platform to extend laterally toward the wafer-level burn-in test device comprises:
after a second bracket that passes through the heat sink in advance receives the target wafer, controlling the second bracket to go down and separate from the heat sink to cause the target wafer to attach to the heat sink;
sucking the target wafer by vacuuming a first vacuum suction air channel in the heat sink, and determining whether the target wafer is sucked on the heat sink and in a preset area of the heat sink; and
if the target wafer is sucked on the heat sink and in the preset area of the heat sink, controlling the mounting platform to extend laterally toward the wafer-level burn-in test device and reach a position below the suction structure of the wafer transfer device.

19. The method according to claim 12, wherein controlling the pressure-bearing platform of the wafer-level burn-in test device to extend laterally toward the heat sink test device after controlling the mounting platform to reset includes:
controlling a second vacuum suction air channel in the pressure-bearing platform to suck the lower sealing cover;
determining whether the lower sealing cover is sucked based on vacuum level information of the second vacuum suction air channel; and
if the lower sealing cover is sucked, controlling the pressure-bearing platform of the wafer-level burn-in test device to extend laterally toward the heat sink test device and reach a position below the suction structure.

20. The method according to claim 12, wherein after the suction structure places the heat sink carrying the target wafer in the lower sealing cover of the pressure-bearing platform, the method further comprises:
sucking the heat sink and the target wafer respectively by vacuuming a second vacuum suction air channel in the pressure-bearing platform;
removing clamp of the heat sink carrying the target wafer by the suction structure; and
controlling the suction structure to reset.

21. The method according to claim 12, wherein controlling the pressure-bearing platform to reset and controlling the lower sealing cover and the cover plate assembly to dock to form the test chamber for the wafer-level burn-in testing comprises:
controlling the pressure-bearing platform to reset;
obtaining position information of the target wafer;
performing coupling alignment between the target wafer and a test probe according to the position information of the target wafer to adjust a position of the target wafer; and
controlling a lifting structure to lift the lower sealing cover upward to connect with the upper cover assembly to form the test chamber for performing the wafer-level burn-in testing on the target wafer.

22. The method according to claim 12, wherein after the wafer-level burn-in testing is completed, the method further includes:
controlling the lower sealing cover to separate from the cover plate assembly and go down to reach the pressure-bearing platform;
controlling the pressure-bearing platform to extend laterally toward the heat sink test device;
controlling the suction structure to take out the heat sink carrying the target wafer from the lower sealing cover;
controlling the pressure-bearing platform to reset:
controlling the mounting platform of the heat sink test device to extend laterally toward the wafer-level burn-in test device;
controlling the suction structure to place the heat sink carrying the target wafer on the mounting platform;
controlling the mounting platform to reset; and
controlling a wafer pick-up device to transfer the target wafer from the heat sink to a wafer cassette.
